(19) United States
(12) Patent Application Publication
(10) Pub. No.: US 2007/0278677 A1
(43) Pub. Date: Dec. 6, 2007

(54) Semiconductor module featuring solder balls having lower melting point than that of solder electrode terminals of passive element device

(75) Inventors: Daisuke Ejima, Kanagawa (JP); Tsuyoshi Kida, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/783,422

(22) Filed: Apr. 9, 2007

(30) Foreign Application Priority Data
Apr. 10, 2006 (JP) 2006-107293

(51) Int. Cl. H01L 23/488

(52) U.S. Cl. 257/738; 257/E23.023

(57) ABSTRACT

In a semiconductor module including a wiring board having a top surface and a bottom surface, a passive element device Is soldered on the top surface of the wiring board by a first solder material, and an external solder electrode terminal is adhered on the bottom surface of the wiring board and made of a second solder material. The first solder material has a higher melting point than that of the second solder material.

### BACKGROUND OF THE INVENTION

1. Field of the Invention

The present invention relates to a semiconductor module including a wiring board, at least one semiconductor device (chip) mounted on a top surface of the wiring board, at least one passive element device mounted on the top surface of the wiring board, and a plurality of solder balls as external electrode terminals adhered to a bottom surface of the wiring board.

2. Description of the Related Art

Recently, a semiconductor module containing at least one semiconductor device and a plurality of passive element devices has been developed. Namely, in such a semiconductor module, the semiconductor device is mounted on a top surface of a wiring board which is called an interposer or a package board, and the passive element devices are soldered on the top surface of the wiring board. The semiconductor device and the passive element devices are sealed by a resin layer formed on the top surface of the wiring board. Also, the wiring board has a plurality of solder balls adhered to a bottom surface of the wiring board, and each of the solder balls serves as an external electrode terminal.

When the semiconductor module is mounted on a motherboard, each of the solder balls is soldered on an electrode pad formed on the motherboard by using a reflow process. Namely, in the reflow process, each of the solder balls is thermally fused and soldered on the electrode pad on the motherboard.

### SUMMARY OF THE INVENTION

It has now been discovered that the above-mentioned prior art semiconductor module has problems to be solved as mentioned hereinbelow.

Conventionally, during the reflow process of the solder balls, the solder material used in the soldering of the passive element device may be thermally fused, and the fused solder material may cause a short circuit in the semiconductor module, as will be stated in detail hereinafter.

In accordance with the present invention, there is provided a semiconductor module including a wiring board having a top surface and a bottom surface, a passive element device soldered on the top surface of the wiring board by a first solder material, and an external solder electrode terminal adhered on the bottom surface of the wiring board and made of a second solder material. The first solder material has a higher melting point than that of the second solder material.

The semiconductor module may further include a semiconductor device mounted on the top surface of the wiring board so that electrical connection is established between the wiring board and the semiconductor device. Also, the semiconductor module may further include a sealing resin layer formed over the top surface of the wiring board to thereby seal the passive element device and the semiconductor device.

The electrical connection may be established by using a bonding wire.

On the other hand, when the semiconductor device is formed as a flip-chip type semiconductor device having a plurality of solder bumps adhered on a front surface thereof, the solder bumps are soldered on the top surface of the wiring board to thereby establish the electrical connection between the wiring board and the semiconductor device. In this case, the solder bumps have a higher melting point than that of the second solder material. Preferably, the melting point of the solder bumps is the same as that of the first solder material.

The passive element device may include a passive element, and a pair of solder electrode terminals for holding the passive element, with the solder electrode terminals being made from the first solder material. The passive element may be any one of a resistor, a capacitor and an inductor.

### BRIEF DESCRIPTION OF THE DRAWINGS

The present invention will be more clearly understood from the description set forth below, with reference to the accompanying drawings, wherein;

FIG. 1 is a cross-sectional view showing a first embodiment of the semiconductor module according to the present invention;

FIG. 2 is a plan view of the semiconductor module of FIG. 1;

FIGS. 3A and 3B are enlarged cross-sectional views of a passive element device of FIG. 1 for explaining a soldering of the passive element device;

FIG. 4 is a cross-sectional view which is similar to FIG. 1;

FIGS. 5A and 5B are enlarged cross-sectional views representatively showing a passive element device included in the semiconductor module of FIG. 4;

FIGS. 6A and 6B are enlarged cross-sectional views representatively showing a passive element device included in the semiconductor module of FIG. 4;

FIGS. 7A and 7B are enlarged cross-sectional views representatively showing a passive element device included in the semiconductor module of FIG. 4;

FIG. 8 is a cross-sectional view, corresponding to FIG. 1, showing a second embodiment of the semiconductor module according to the present invention;

FIG. 9 is a plan view of the semiconductor module of FIG. 8; and

FIG. 10 is a cross-sectional view which is similar to FIG. 8.

### DESCRIPTION OF THE PREFERRED EMBODIMENTS

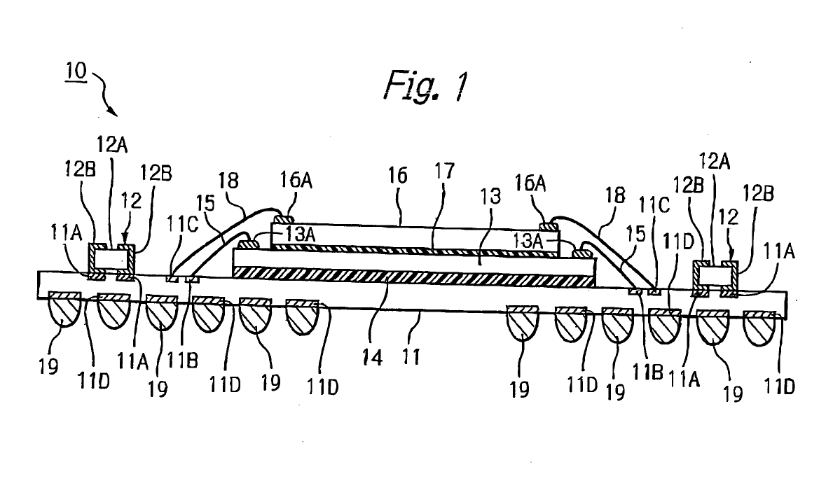

With reference to FIGS. 1, 2, 3 and 4, a first embodiment of the semiconductor module according to the present invention will now be explained below.

First, referring to FIG. 1 which is a cross-sectional view of the semiconductor module, the semiconductor module is generally indicated by reference 10.

The semiconductor module 10 includes a wiring board 11 which is called an interposer or a package board. Plural pairs of electrode pads 11A, a plurality of electrode pads 11B and a plurality of electrode pads 11C are formed on a top surface of the wiring board 11. Also, a plurality of electrode pads 11D are formed on a bottom surface of the wiring board 11.

The semiconductor module 10 also includes a plurality of passive element devices 12 mounted on the top surface of the wiring board 11, and each of the passive element devices 12 includes a passive element 12A such as a resistor, a capacitor or an inductor, and a pair of electrode terminals 12B for holding the passive element 12A. The pair of electrode terminals 12B of the passive element device 12 are made of a suitable solder material, and are soldered on a corresponding pair of electrode pads 11A of the wiring board 11 in a manner as will be stated In detail hereinafter.

For the solder electrode terminals 12B of the passive element devices 12, a solder material having a high melting point of more than 200° C. is used. For example, it is possible to use any one of the solder materials having the high melting points of 217° C., 227° C. and 240° C. for the solder electrode terminals 18B. The solder material having the melting point 217° C. may be composed of a 96.5 w % tin (Sn) component, a 3.0 w % silver (Ag) component and a 0.5 w % copper (Cu) component. Also, the solder material having the melting point of 227° C. may be composed of a 99.25 w % tin (Sn) component and a 0.75 w % copper (Cu) component. Further, the solder material having the melting point of 240° C. may be composed of a 99.5 w % tin (Sn) component and a 0.5 w % antimony (Sb) component.

The semiconductor module 10 is provided with a semiconductor device (chip) 13 mounted on the top surface of the wiring board 11 in such a manner that a rear surface of the semiconductor device 13 is adhered to the top surface of the wiring board 11 by using a suitable adhesive layer 14. The semiconductor device 13 has a plurality of electrode pads 13A formed on a front surface thereof, and each of the electrode pads 13A is electrically connected to a corresponding one of the electrode pads 11B on the wiring board 11 by a bonding wire 15, using a wire bonding machine (not shown).

The semiconductor module 10 is also provided with a semiconductor device 16 mounted on the front surface of the semiconductor device 13 in such a manner that a rear surface of the semiconductor device 16 is adhered to the front surface of the semiconductor device 13 by using a suitable adhesive layer 17. The semiconductor device 16 has a plurality of electrode pads 16A formed on a front surface thereof, and each of the electrode pads 16A is electrically connected to a corresponding one of the electrode pads 11C on the wiring board It by a bonding wire 18, using a wire bonding machine (not shown).

The semiconductor module 10 is further provided with a plurality of solder balls 19 which are soldered on the respective electrode pads 11D on the bottom surface of the wiring board 11, and each of the solder balls 19 serves as an external electrode terminals.

For the solder balls 19, a solder material having a low melting point of less than 200° C. is used. For example, it is possible to use the solder material having the melting point of 190° C. for the solder balls 19. The solder material having the melting point of 190° C. may be composed of a 89.0 w % tin (Sn) component, a 8.0 w % zinc (Zn) component and a 3.0 w % bismuth (Bi) component.

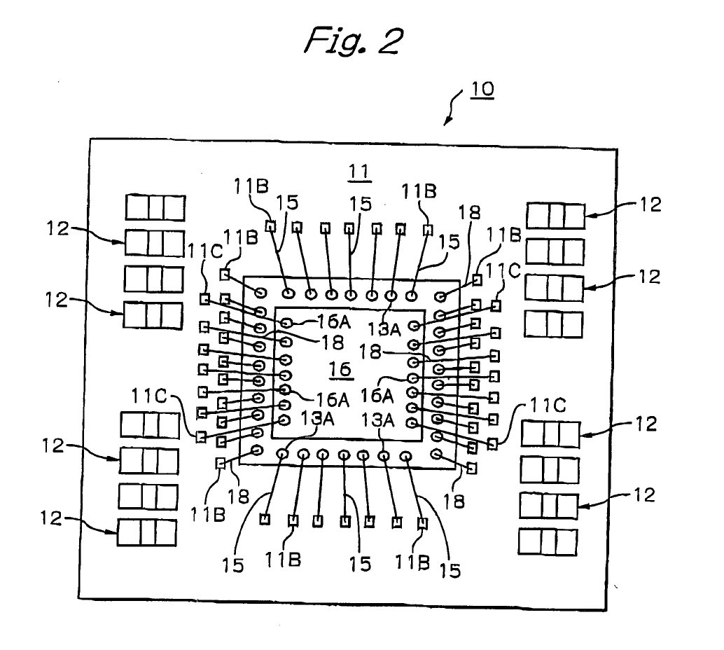

Referring to FIG. 2 which is a plan view of FIG. 1, the wiring board 11 has a rectangular configuration, and the passive element devices 12 are regularly arranged on the top surface of the wiring board 11 along opposite sides of the wiring board 11. Note that the passive element devices 12 may further arranged along the other opposite sides of the wiring board 11, if necessary.

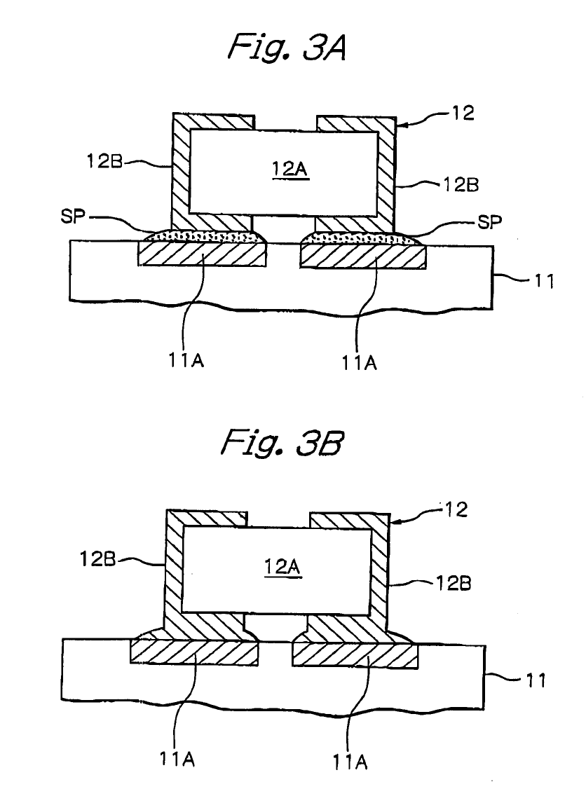

Next, with reference to FIGS. 3A and 3B, the mounting of the passive element device 12 on the wiring board 11 will be explained below.

First, referring to FIG. 3A which is an enlarged cross-sectional view, pieces of solder paste SP are previously deposited on to the electrode pads 11A by using a silk printing process, and the respective solder electrode terminals 12B of the passive element device 12 are placed on the corresponding pieces of solder paste SP on the electrode pads 11A. Note that the solder paste SP comprises a flux solution containing the same solder material as that of the solder electrode terminals 12B. Then, the pieces of solder paste SP and the solder electrode terminals 12B are subjected to a so-called reflow process.

Next, as shown in FIG. 3B which is an enlarged cross-sectional view, during the reflow process, the respective solder materials contained in the pieces of solder paste SP are thermally fused to be thereby integrated with the solder electrode terminals 12B, resulting in completion of the soldering of the passive element devices 12 on the electrode pads 11C.

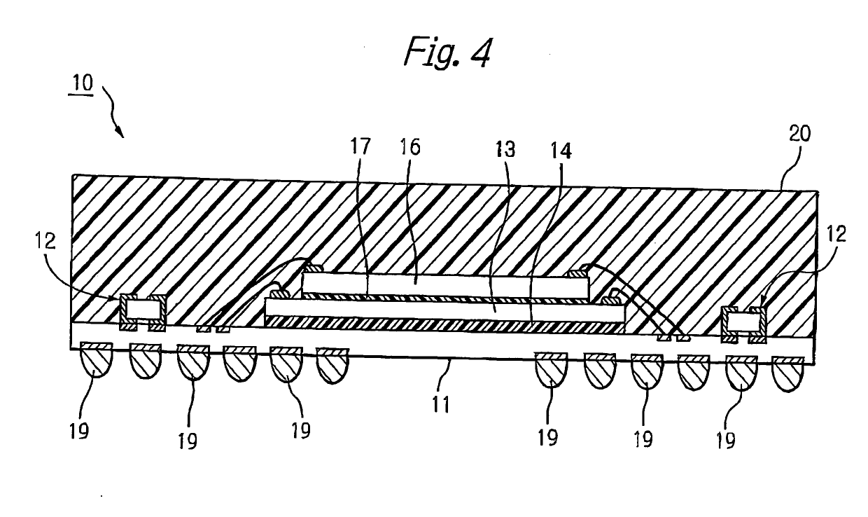

Next, referring to FIG. 4 which is similar to FIG. 1, a seal resin layer 20 is formed on the semiconductor module 10 (see: FIG. 1) so that the semiconductor devices 13 and 16, the passive element devices 12 and so on are sealed in the seal resin layer 20, resulting in completion of the manufacture of a ball grid array (BGA) type semiconductor module 10. Note that the formation of the seal resin layer 20 may be carried out by using a transfer molding process.

When the BGA type semiconductor module 10 of FIG. 4 is mounted on a motherboard (not shown) so that the respective solder balls 19 are soldered on electrode pads formed on the motherboard, the solder balls 19 are subjected to a reflow process at a temperature of less than 200° C. Thus, it is possible to carry out the soldering of the solder balls 19 on the electrode pads of the motherboard without thermally fusing (reflowing) the solder electrode terminals 12B of the passive element devices 12, because the melting point of the solder electrode terminals 12B is higher than that of the solder balls 19, as stated above.

If the solder electrode terminals 12B of the passive element devices 12 have the melting point which is equivalent or less than that of the solder balls 19, the BGA type semiconductor module 10 of FIG. 4 may suffer disadvantages due to the fact that fine clearances are apt to be defined in the seal resin layer 20 around the passive element devices 12, as will be stated below.

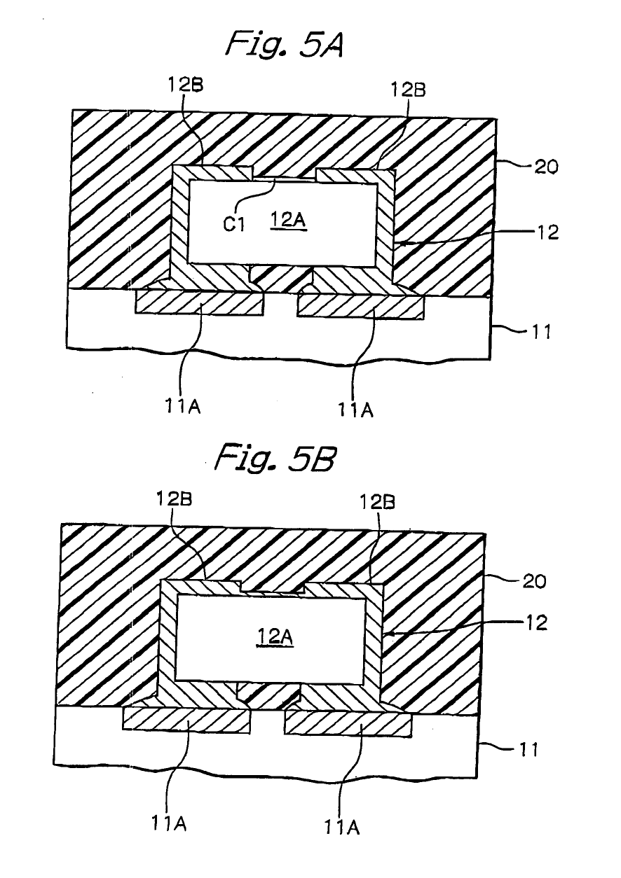

First, referring to FIG. 5A which is an enlarged cross-sectional view, the passive element device 12 is sealed in the seal resin layer 20, but a fine clearance C1 may be defined in the seal resin layer 20 at a top surface of the passive element 18A between the solder electrode terminals 12B.

Next, referring to FIG. 5B which is similar to FIG. 5A, during the reflow process of the solder balls 19, the solder electrode terminals 112B are thermally fused so that the fused solder may penetrate into the clearance C1 due to a capillary phenomenon, resulting in occurrence of a short circuit between the solder electrode terminals 12B.

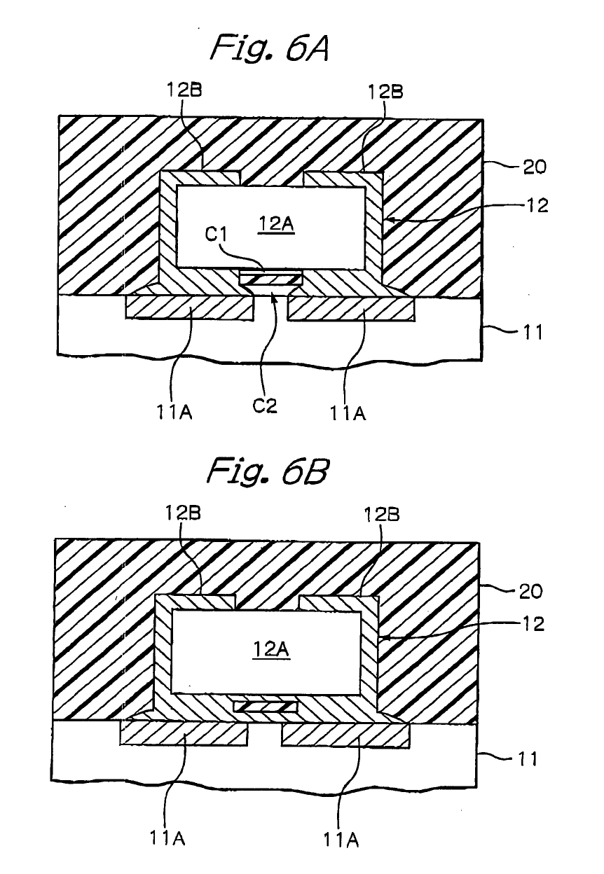

Also, referring to FIG. 6A which is an enlarged cross-sectional view, the passive element device 12 is sealed in the seal resin layer 20, but fine clearances C2 and C3 may be defined in the seal resin layer 20 at a bottom surface of the passive element 12A between the solder electrode terminals 12B.

Next, referring to FIG. 6B which is similar to FIG. 6A, during the reflow process of the solder balls 19, the solder electrode terminals 12B are thermally fused so that the fused solder may penetrate into the clearances C2 and C3 due to a capillary phenomenon, resulting in occurrence of a short circuit between the solder electrode terminals 12B.

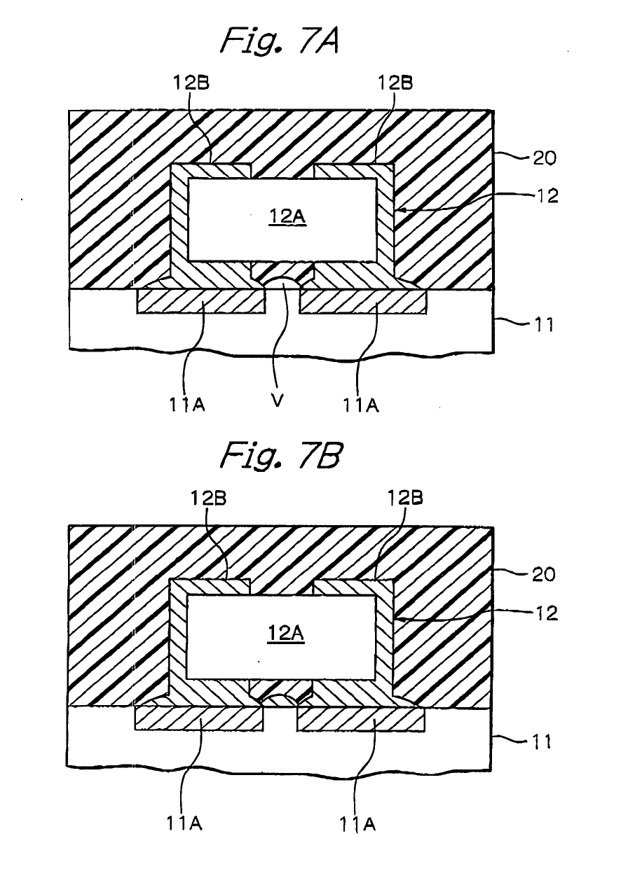

Further, referring to FIG. 7A which is an-enlarged cross-sectional view, the passive element device 12 is sealed in the seal resin layer 20, but a fine void V may be defined in the seal resin layer 20 beneath the bottom surface of the passive element 12A between the solder electrode terminals 12B.

Next, referring to FIG. 7B which is similar to FIG. 7A, during the reflow process of the solder balls 19, the solder electrode terminals 12B are thermally fused so that the fused solder may penetrate into the void V due to a capillary phenomenon, resulting in occurrence of a short circuit between the solder electrode terminals 12B.

As stated above, in the semiconductor module 10 of FIG. 4, it is possible to carry out the soldering of the solder balls 19 on the electrode pads of the motherboard without thermally fusing (reflowing) the solder electrode terminals 12B of the passive element devices 12. Thus, although the fine clearances C1, C2 and C3 and the void V are defined in the seal resin layer 20 around the passive element devices 12, the semiconductor module 10 of FIG. 4 is free from the aforesaid short circuit problem (see: FIGS. 5A and 5B, FIGS. 6A and 6B and FIGS. 7A and 7).

### Second Embodiment

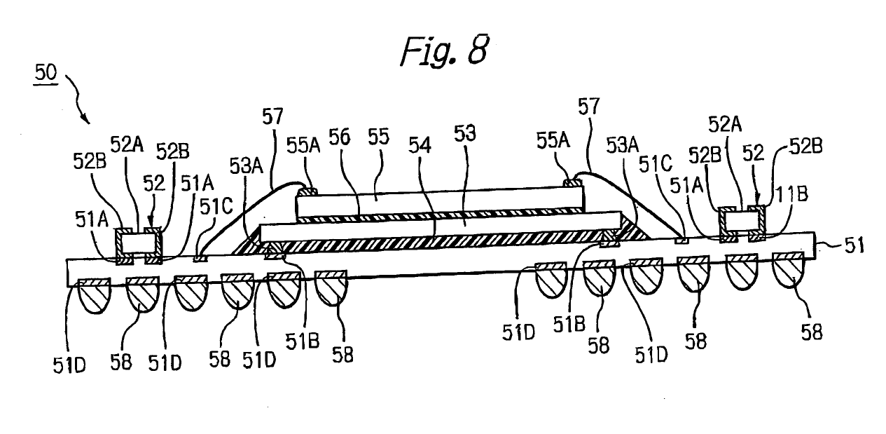

With reference to FIGS. 8, 9 and 10, a second embodiment of the semiconductor module according to the present invention is explained below.

First, referring to FIG. 8 which is a cross-sectional view of the semiconductor module, the semiconductor module is generally indicated by reference 50.

Similar to the aforesaid first embodiment of FIGS. 1 to 4, the semiconductor module 50 includes a wiring board 51 which is called an interposer or a package board. Plural pairs of electrode pads 51A, a plurality of electrode pads 51B, and a plurality of electrode pads 51C are formed on a top surface of the Wiring board 51. Also, a plurality of electrode pads 51D are formed on a bottom surface of the wiring board 51.

Also, the semiconductor module 50 includes a plurality of passive element devices 52 mounted on the top surface of the wiring board 51, and each of the passive element devices 52 includes a passive element 52A such as a resistor, a capacitor or an inductor, and a pair of electrode terminals 52B for holding the passive element 52A. The pair of electrode terminals 52B of the passive element device 52 are made of a suitable solder material, and are soldered on a corresponding pair of electrode pads 51A of the wiring board 51 by using a so-called reflow process, in a similar manner to that stated above with reference to FIGS. 3A and 3B.

Note, similar to the aforesaid first embodiment of FIGS. 1 to 4, for the solder electrode terminals 52B of the passive element devices 52, a solder material having a high melting point of more than 200° C. is used.

The semiconductor module 50 is provided with a flip-chip type semiconductor device (chip) 53 mounted on the top surface of the wiring board 51. In particular, the flip-chip type semiconductor device 53 has solder bumps 53A which are adhered on electrode pads (not shown) formed on a front surface thereof, and the mounting of the flip-chip type semiconductor device 53 on the wiring board 51 is carried out so that the solder bumps 53A are soldered on the electrode pads 51B.

Each of the solder bumps 53A is composed of a solder material having a high melting point of more than 200° C. Preferably, each of the solder bumps 53A is made of the same material as that of the solder electrode terminals 52B of the passive element devices 52. In short, when the electrode terminals 52B of the passive element devices 52 are soldered on the electrode pads 51A by using the reflow process, it is possible to simultaneously carry out the soldering of the solder bumps 53A on the electrode pads 51B.

After the soldering of the solder bumps 53A on the electrode pads 51B is completed, the flip-chip semiconductor device 53 is subjected to an underfilling process in which a suitable resin material is introduced into a space between the wiring board 11 and the flip-chip semiconductor device 53 to thereby form a sealing resin layer 54 therebetween. Namely, the front surface of the flip-chip semiconductor device 53, the electrode pads 518, the solder bumps 53A and so on are sealed and protected by the sealing resin layer 54.

The semiconductor module 50 is also provided with a semiconductor device (chip) 55 mounted on a rear surface of the flip-chip semiconductor device 53 in such a manner that a rear surface of the semiconductor device 55 is adhered to the rear surface of the flip-chip semiconductor device 53 by using a suitable adhesive layer 56. The semiconductor device 55 has a plurality of electrode pads 55A formed on a front surface thereof, and each of the electrode pads 55A is electrically connected to a corresponding one of the electrode pads 51C on the wiring board 51 by a bonding wire 57, using a wire bonding machine (not shown).

The semiconductor module 50 is further provided with a plurality of solder balls 58 which are soldered on the respective electrode pads 51D on the bottom surface of the wiring board 11, and each of the solder balls 58 serves as an external electrode terminal.

Similar to the aforesaid first embodiment of FIGS. 1 to 4, for the solder balls 58, a solder material having a low melting point of less than 200° C. is used.

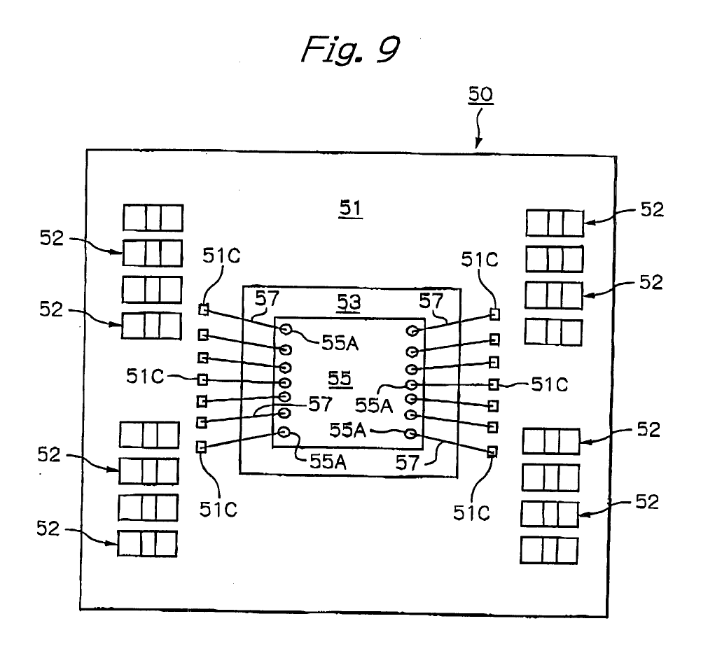

Referring to FIG. 9 which is a plan view of FIG. 8, the wiring board 51 has a rectangular configuration, and the passive element devices 52 are regularly arranged on the top surface of the wiring board 51 along opposite sides of the wiring board 51. Note that the passive element devices 52 may further arranged along the other opposite sides of the wiring board 51, if necessary.

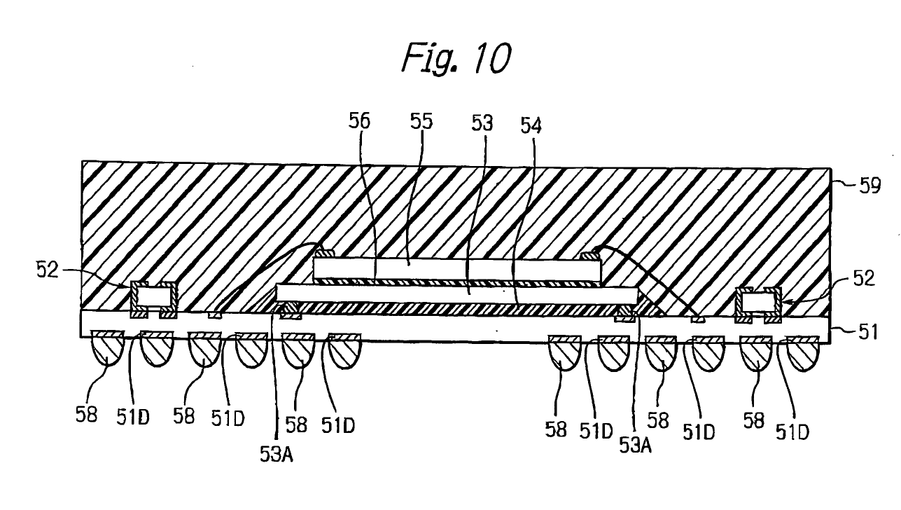

Next, referring to FIG. 10 which is similar to FIG. 8, a resin layer 59 is formed on the semiconductor module 50 (see: FIG. 8) so that the semiconductor chips 53 and 55, the passive element devices 52 and so on are sealed in the resin layer 59, resulting in completion of a manufacture of a ball grid array (BGA) type semiconductor module 50. Note that the formation of the resin layer 59 may be carried out by using a transfer molding process.

Similar to the aforesaid first embodiment of FIGS. 1 to 4, when the BGA type semiconductor module of FIG. 10 is mounted on a motherboard (not shown) so that the respective solder balls 58 are soldered on electrode pads formed on the motherboard, the solder balls 58 are subjected to a reflow process at a temperature of less than 200° C. Thus, it is possible to carry out the soldering of the solder balls 58 on the electrode pads of the motherboard without thermally fusing (reflowing) the solder electrode terminals 52B of the passive element devices 52 and the solder bumps 53A of the flip-chip type semiconductor device 53, because the melting point of the solder electrode terminals 52B and the solder bumps 53A is higher than that of the solder balls 58, as stated above. Thus, the semiconductor module 50 of FIG. 10 is free from the 20 aforesaid short circuit problem (see: FIGS. 5A and 5B, FIGS. 6A and 6B and FIGS. 7A and 7).

JP-2004-259886 A discloses a structure of a package on package (POP) type semiconductor module which includes a lower semiconductor package, and an upper semiconductor package mounted on the lower semiconductor package. Each of the lower and upper semiconductor packages has solder balls or bumps as external electrode terminals, and the solder bumps of the upper semiconductor package have a higher melting point than that of the solder bumps of the lower semiconductor package. Nevertheless, JP-2004-259886 A fails to mention solder materials used in the lower and upper semiconductor packages. Namely, JP-2004-259886 A makes no reference to a relationship between the melting points of the solder bumps of the upper semiconductor package and the solder materials used in the lower and upper semiconductor packages.

Finally, it will be understood by those skilled in the art that the foregoing description is of preferred embodiments of the semiconductor module, and that various changes and modifications may be made to the present invention without departing from the spirit and scope thereof.

1. A semiconductor module comprising:
a wiring board having a top surface and a bottom surface;
a passive element device soldered on the top surface of said wiring board by a first solder material; and
an external solder electrode terminal adhered on the bottom surface of said wiring board and made of a second solder material,
wherein said first solder material has a higher melting point than that of said second solder material.

2. The semiconductor module as set forth in claim 1, further comprising a semiconductor device mounted on the top surface of said wiring board so that electrical connection is established between said wiring board and said semiconductor device.

3. The semiconductor module as set forth in claim 2, further comprising a sealing resin layer formed over the top surface of said wiring board to thereby seal said passive element device and said semiconductor device.

4. The semiconductor module as set forth in claim 2, wherein the electrical connection is established by using a bonding wire.

5. The semiconductor module as set forth in claim 2, wherein said semiconductor device is formed as a flip-chip type semiconductor device having a plurality of solder bumps adhered on a front surface thereof, said solder bumps being soldered on the top surface of said wiring board to thereby establish the electrical connection between said wiring board and said semiconductor device.

6. The semiconductor module as set forth in claim 5, wherein said solder bumps have a higher melting point than that of said second solder material.

7. The semiconductor module as set forth in claim 5, wherein the melting point of said solder bumps is the same as that of said first solder material.

8. The semiconductor module as set forth in claim 1, wherein said passive element device includes a passive element.

9. The semiconductor module as set forth in claim 8, wherein said passive element device further includes a pair of solder electrode terminals for holding said passive element, with the solder electrode terminals being made from said first solder material.

10. The semiconductor module as set forth in claim 8, wherein said passive element is a resistor.

11. The semiconductor module as set forth in claim 8, wherein said passive element is a capacitor.

12. The semiconductor module as set forth in claim 8, wherein said passive element is an inductor.
